(19) United States
(12) Patent Application Publication
(10) Pub. No.: US 2016/0035669 A1
(43) Pub. Date: Feb. 4, 2016

(54) ROUTING PATHS AND SEMICONDUCTOR DEVICES INCLUDING THE SAME

(71) Applicant: SK hynix Inc., Icheon-si (KR)

(72) Inventor: Won John Choi, Seongnam-si (KR)

(21) Appl. No.: 14/811,674

(22) Filed: Jul. 28, 2015

(30) Foreign Application Priority Data
Jul. 31, 2014 (KR) 10-2014-0098240

(51) Int. Cl. H01L 23/522

(52) U.S. Cl. CPC H01L 23/5226

(57) ABSTRACT

A semiconductor device may include a global line coupled to a source, and a plurality of local lines coupled to a plurality of targets, respectively, and coupled to the global line. The local lines may be configured to have cross-sectional areas. The cross-sectional areas may increase in proportion to distances from the source to the respective targets.

### CROSS-REFERENCES TO RELATED APPLICATION

The present application claims priority under 35 U.S.C. §119(a) to Korean Patent Application No. 10-2014-0098240, filed on Jul. 31, 2014, in the Korean Intellectual Property Office, which is incorporated herein by reference in its entirety.

### BACKGROUND

1. Technical Field

Various embodiments generally relate to routing paths and a semiconductor design technology, and more particularly, to a semiconductor device with routing paths for transmitting signals.

2. Related Art

Signals used in a semiconductor device are designed to have different margins. In particular, with the increase in an operating speed of the semiconductor device, securing a setup/hold time of signals synchronized with a clock is becoming an important factor for the reliability of the semiconductor device.

Recently, with the decrease in size of the semiconductor device and the increase in number of functions included in the semiconductor device, the limit of allowable skew has gradually decreased. Research has been conducted to reduce this skew.

### SUMMARY

In an embodiment, a semiconductor device may be provided. The semiconductor device may include a global line coupled to a source, and a plurality of local lines coupled to a plurality of targets, respectively, and coupled to the global line. The local lines may be configured to have cross-sectional areas. The cross-sectional areas may increase in proportion to distances from the source to the respective targets.

In an embodiment, a semiconductor device may be provided. The semiconductor device may include a global line coupled to a source, and a plurality of local lines coupled to a plurality of targets, respectively, and arranged at a different layer from a layer at which is the global line is arranged. The semiconductor device may include one or more vias formed at each of intersections between the global line and the local lines to couple the global line and the corresponding local line. The vias formed in the respective intersections may be configured to have total cross-sectional areas. The total cross-sectional areas may increase in proportion to distances from the source to the respective targets.

In an embodiment, a semiconductor device may be provided. The semiconductor device may include a global line coupled to an output, and a plurality of local lines coupled to a plurality of inputs, respectively, and coupled to the global line. The local lines may be configured to have cross-sectional areas. The cross-sectional areas may increase in proportion to distances from the source to the respective targets.

In an embodiment, routing pats may be provided. The routing paths may include a global line, and a plurality of local lines coupled to the global line. The length of a routing path includes a section of the global line and a length of a local line. The loading differences may be based on length differences between the routing paths are minimized by increasing or decreasing a cross-sectional area of a local line.

### BRIEF DESCRIPTION OF THE DRAWINGS

FIG. 1 is a layout diagram illustrating a representation of an is example of a semiconductor device in accordance with an embodiment.

FIG. 2 is a layout diagram illustrating a representation of an example of a semiconductor device in accordance with an embodiment.

FIG. 3 is a cross-sectional illustration of a representation of an example of a view taken along I-I′ of FIG. 2.

FIG. 4 is a layout diagram illustrating a representation of an example of a semiconductor device in accordance with an embodiment.

FIG. 5 is a cross-sectional illustration of a representation of an example of a view taken along II-II′ of FIG. 4.

FIG. 6 illustrates a block diagram of an example of a representation of a system employing a semiconductor device in accordance with the various embodiments discussed above with relation to FIGS. 1-5.

### DETAILED DESCRIPTION

Hereinafter, a semiconductor device will be described below with reference to the accompanying drawings through various examples of embodiments.

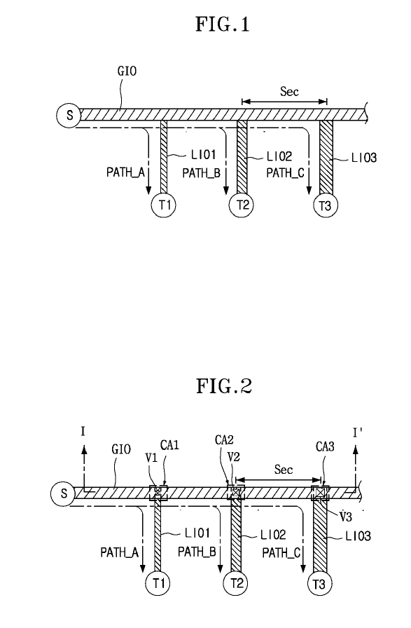

Referring to FIG. 1, a global line GIO coupled to a source S may be arranged in one direction. The global line GIO may be coupled to a plurality of local lines LIO1 to LIO3 coupled to a plurality of targets T1 to T3, respectively, and the local lines LIO1 to LIO3 may be arranged in a direction crossing the global line GIO. FIG. 1 illustrates a structure including one source and three targets, for example. However, the embodiments are not limited in this manner and any number of targets and sources may be included in a structure.

In a semiconductor device, a signal may be transmitted from a specific output (for example, driver) to a plurality of inputs (for example, gates of transistors). The source S may include an output serving as a supply source for providing a signal, and the targets T1 to T3 may include an input for receiving the signal.

In an embodiment, the first to third local lines LIO1 to LIO3 may be arranged at the same layer as the global line GIO, and may be directly coupled to the global line GIO.

The global line GIO and the first to third local lines LIO1 to LIO3 may provide first to third routing paths PATH_A to PATH_C for transmitting a signal from one source S to the first to third targets T1 to T3.

Depending on the positions of the respective targets T1 to T3, distances from the source S to the respective targets T1 to T3 may differ from each other. For example, the first to third routing paths PATH_A to PATH_C may have different lengths. For example, due to a positional difference between the first and third targets T1 and T3, the length of the third routing path PATH_C for transmitting a signal from the source S to the third target T3 may be larger by the length of a section Sec than the length of the first routing path PATH_A for transmitting a signal from the source S to the first target T1.

Thus, the loading of the third routing path PATH_C may be larger by the loading of the section Sec than the loading of the first routing path PATH_A. The time during which a signal from the source S is transmitted to the third target T3 may be longer than the time during which the signal from the source S is transmitted to the first target T1. That is, a skew may occur.

In an embodiment, the local lines LIO1 to LIO3 may be configured to have cross-sectional areas. The cross-section areas of the local lines LIO1 to LIO3 may increase in proportion to the distances from the source S to the respective targets T1 to T3. That is, when the cross-sectional area of the first local line LIO1 coupled to the first target T1 which is the closest to the source S is represented by A1, the cross-sectional area of the second local line LIO2 coupled to the second target T2 which is the second closest to the source S is represented by A2, and the cross-sectional area of the third local line LIO3 coupled to the third target T3 which is the furthest from the source S is represented by A3, the relation of A3>A2>A1 may be satisfied.

The loading of a line is inversely proportional to the cross-sectional area of the line. Thus, when the local lines LIO1 to LIO3 are configured to have cross-sectional areas which increase in proportion is to the distances from the source S to the respective targets T1 to T3, the loadings of the local lines LIO1 to LIO3 may decrease in proportion to the distances from the source S to the targets coupled to the respective local lines LIO1 to LIO3. Thus, since the loading of a local line on a routing path having a relatively large length becomes smaller than the loading of a local line on a routing path having a relatively small length, a loading difference based on the length difference between the routing paths can be compensated for.

FIG. 1 illustrates an example in which the global line GIO and the local lines LIO1 to LIO3 are formed at the same layer. However, the global line GIO and the local lines LIO1 to LIO3 may be formed at different layers. This configuration will be obvious through the following descriptions with reference to FIGS. 2 to 5.

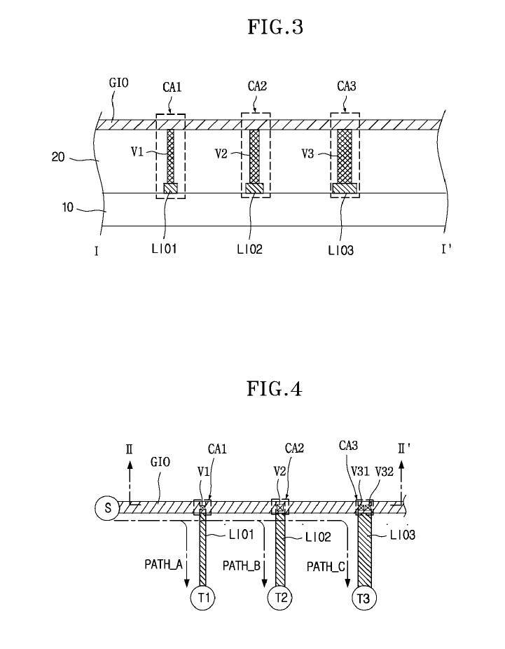

Referring to FIGS. 2 and 3, a global line GIO coupled to a source S may be arranged in one direction. The global line GIO may be coupled to a plurality of local lines LIO1 to LIO3 coupled to a plurality of targets T1 to T3, respectively, and may be arranged in a direction crossing the global line GIO. FIGS. 2 and 3 illustrate a structure including one source and three targets, for example. However, the embodiments are not limited in this manner and any number of targets and sources may be included in a structure.

The local lines LIO1 to LIO3 may be formed over a base layer 10. Although not illustrated, the targets T1 to T3 may be formed over the base layer 10, like the local lines LIO1 to LIO3. In an embodiment, it has been described that the plurality of targets T1 to T3 are formed at the same layer. However, the embodiments are not limited thereto, but the targets T1 to T3 may be formed at two or more different layers.

Over the base layer 10, an interlayer dielectric layer 20 may be formed to cover the targets T1 to T3 and the local lines LIO1 to

LIO3, and the global line GIO may be formed over the interlayer dielectric layer 20. In an embodiment, the local lines LIO1 to LIO3 may be formed at a first metal layer M1, and the global line GIO may be formed at a second metal layer M2 over the first metal layer M1.

At intersections CA1 to CA3 between the global line GIO and the local lines LIO1 to LIO3, vias V1 to V3 may be formed to couple the global line GIO to the local lines LIO1 to LIO3, respectively, through the interlayer dielectric layer 20. In an embodiment, one via may be formed for each of the intersections CA1 to CA3. For example, a first via represented by V1 may be formed at the intersection CA1 between the global line GIO and the first local line LIO1, a second via represented by V2 may be formed at the intersection CA2 between the global line GIO and the second local line LIO2, and a third via represented by V3 may be formed at the intersection CA3 between the global line GIO and the third local line LIO3.

The global line GIO, the first to third vias V1 to V3, and the first to third local lines LIO1 to LIO3 may provide first to third routing paths PATH_A to PATH_C for transmitting a signal from one source S to the first to third targets T1 to T3.

Depending on the positions of the respective targets T1 to T3, distances from the source S to the respective targets T1 to T3 may differ from each other. That is, the first to third routing paths PATH_A to PATH_C may have different lengths. For example, due to a positional difference between the first and third targets T1 and T3, the length of the third routing path PATH_C for transmitting a signal from the source S to the third target T3 may be larger by the length of a section Sec than the length of the first routing path PATH_A for transmitting a signal from the source S to the first target T1.

The loading of the third routing path PATH_C may be larger by the loading of the section Sec than the loading of the first routing path PATH_A. The time during which a signal from the source S is transmitted to the third target T3 may be longer than the time during which the signal from the source S is transmitted to the first target T1. That is, a skew may occur.

In an embodiment, the vias V1 to V3 formed at the respective intersections CA1 to CA3 may be configured to have cross-sectional areas. The cross-sectional areas of the vias V1 to V3 may increase in proportion to the distances from the source S to the respective targets T1 to T3. That is, when the cross-sectional area of the first via V1 formed at the intersection CA1 corresponding to the first target T1 which is the closest to the source S is represented by S1, the cross-sectional area of the second via V2 formed at the intersection CA2 corresponding to the second target T2 which is the second closest to the source S is represented by S2, and the cross-sectional area of the third via V3 formed at the intersection CA3 corresponding to the third target T3 which is the furthest from the source S is represented by S3, the relation of S3>S2>S1 may be satisfied.

The loading of a via is inversely proportional to the cross-sectional area of the via. Thus, when the vias V1 to V3 are configured to have cross-sectional areas which increase in proportion to the distances from the source S to the respective targets T1 to T3, the loadings of the vias V1 to V3 may decrease in proportion to the distances from the source S to the respective targets T1 to T3. Thus, since the loading of a via on a routing path having a relatively large length becomes smaller than the loading of a via on a routing path having a relatively small length, a loading difference based on the length difference between the routing paths can be compensated for.

Furthermore, the local lines LIO1 to LIO3 may be configured to have cross-sectional areas. The cross-sectional areas LIO1 to LIO3 may increase in proportion to the distances from the source S to the respective targets T1 to T3. That is, when the cross-sectional area of the first local line LIO1 coupled to the first target T1 which is the closest to the source S is represented by A1, the cross-sectional area of the second local line LIO2 coupled to the second target T2 which is the second closest to the source S is represented by A2, and the cross-sectional area of the third local line LIO3 coupled to the third target T3 which is the furthest from the source S is represented by A3, the relation of A3>A2>A1 may be satisfied.

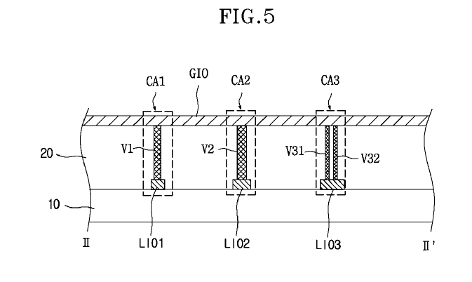

FIGS. 2 and 3 illustrate an example in which one via is formed in each of the intersections CA1 to CA3. However, the embodiments are not limited thereto, but two or more vias may be formed at one or more of the intersections CA1 to CA3. For example, as illustrated in FIGS. 4 and 5, two vias V31 and V32 may be formed at the intersection CA3 between the global line GIO and the third local line LIO3.

The vias V31 and V32 formed at the intersection CA3 between the global line GIO and the third local line LIO3 may be coupled in parallel between the global line GIO and the third local line LIO3.

Furthermore, the vias V1, V2, and V31 and V32 formed at the respective intersections CA1 to CA3 may be configured to have total cross-sectional areas which increase in proportion to the distances from the source S to the respective targets T1 to T3. That is, when the cross-sectional area of the first via V1 formed at the intersection CA1 corresponding to the first target T1 which is the closest to the source S is represented by S1, the cross-sectional area of the second via V2 formed at the intersection CA2 corresponding to the second target T2 which is the second closest to the source S is represented by S2, and the cross-sectional areas of the third vias V31 and V32 formed at the intersection CA3 corresponding to the third target T3 which is the furthest from the source S is represented by S31 and S32, the relation of S31+S32>S2>S1 may be satisfied.

Additionally, the local lines LIO1 to LIO3 may be configured to have cross-sectional areas. The cross-sectional areas LIO1 to LIO3 may increase in proportion to the distances from the source S to the respective targets T1 to T3. That is, when the cross-sectional area of the first local line LIO1 coupled to the first target T1 which is the closest to the source S is represented by A1, the cross-sectional area of the second local line LIO2 coupled to the second target T2 which is the second closest to the source S is represented by A2, and the cross-sectional area of the third local line LIO3 coupled to the third target T3 which is the furthest from the source S is represented by A3, the relation of A3>A2>A1 may be satisfied.

In accordance with the embodiments, as a local line or/and a via on a routing path having a relatively large length is/are configured to have a larger cross-sectional area than a local line or/and a via on a routing path having a relatively small length, a loading difference based on the length difference between the routing paths can be compensated for, and a skew can be removed.

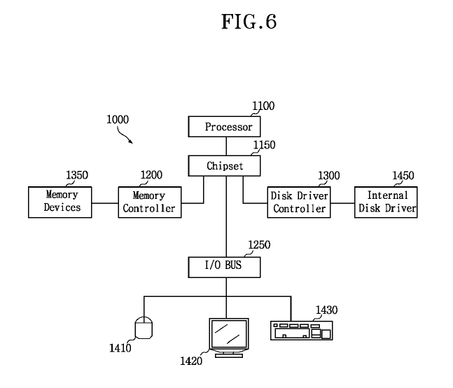

The semiconductor devices discussed above (i.e., see FIGS. 1-5) are particular useful in the design of memory devices, processors, and computer systems. For example, referring to FIG. 6, a block diagram of a system employing a semiconductor device in accordance is with the various embodiments are illustrated and generally designated by a reference numeral 1000. The system 1000 may include one or more processors (i.e., Processor) or, for example but not limited to, central processing units (“CPUs”) 1100. The processor (i.e., CPU) 1100 may be used individually or in combination with other processors (i.e., CPUs). While the processor (i.e., CPU) 1100 will be referred to primarily in the singular, it will be understood by those skilled in the art that a system 1000 with any number of physical or logical processors (i.e., CPUs) may be implemented.

A chipset 1150 may be operably coupled to the processor (i.e., CPU) 1100. The chipset 1150 is a communication pathway for signals between the processor (i.e., CPU) 1100 and other components of the system 1000. Other components of the system 1000 may include a memory controller 1200, an input/output (“I/O”) bus 1250, and a disk driver controller 1300. Depending on the configuration of the system 1000, any one of a number of different signals may be transmitted through the chipset 1150, and those skilled in the art will appreciate that the routing of the signals throughout the system 1000 can be readily adjusted without changing the underlying nature of the system 1000.

As stated above, the memory controller 1200 may be operably coupled to the chipset 1150. The memory controller 1200 may include at least one semiconductor device as discussed above with reference to FIGS. 1-5. Thus, the memory controller 1200 can receive a request provided from the processor (i.e., CPU) 1100, through the chipset 1150. In alternate embodiments, the memory controller 1200 may be integrated into the chipset 1150. The memory controller 1200 may be operably coupled to one or more memory devices 1350. In an embodiment, the memory devices 1350 may include the at least one semiconductor device as discussed above with relation to FIGS. 1-5, the memory devices 1350 may include a plurality of word lines and a plurality of bit lines for defining a plurality of memory cells. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may also be coupled to the I/O bus 1250. The I/O bus 1250 may serve as a communication pathway for signals from the chipset 1150 to I/O devices 1410, 1420, and 1430. The I/O devices 1410, 1420, and 1430 may include, for example but are not limited to, a mouse 1410, a video display 1420, or a keyboard 1430. The I/O bus 1250 may employ any one of a number of communications protocols to communicate with the I/O devices 1410, 1420, and 1430. In an embodiment, the I/O bus 1250 may be integrated into the chipset 1150.

The disk driver controller 1300 may be operably coupled to the chipset 1150. The disk driver controller 1300 may serve as the communication pathway between the chipset 1150 and one internal disk driver 1450 or more than one internal disk driver 1450. The internal disk driver 1450 may facilitate disconnection of the external data storage devices by storing both instructions and data. The disk driver controller 1300 and the internal disk driver 1450 may communicate with each other or with the chipset 1150 using virtually any type of communication protocol, including, for example but not limited to, all of those mentioned above with regard to the I/O bus 1250.

It is important to note that the system 1000 described above in relation to FIG. 6 is merely one example of a system 1000 employing a semiconductor device as discussed above with relation to FIGS. 1-5. In alternate embodiments, such as, for example but not limited to, cellular phones or digital cameras, the components may differ from the embodiments illustrated in FIG. 6.

While various embodiments have been described above, it will be understood to those skilled in the art that the embodiments described are by way of example only. Accordingly, the semiconductor device described herein should not be limited based on the described embodiments.

What is claimed is:

1. A semiconductor device comprising:
a global line coupled to a source; and
a plurality of local lines coupled to a plurality of targets, respectively, and coupled to the global line,
wherein the local lines are configured to have cross-sectional areas, and
wherein the cross-sectional areas increase in proportion to distances from the source to the respective targets.

2. The semiconductor device of claim 1, wherein the global line and the local lines are formed at different layers.

3. The semiconductor device of claim 2, further comprising one or more vias formed at each intersection between the global line and the local lines to couple the global line and the corresponding local line,
wherein the vias formed at the respective intersections are configured to have total cross-sectional areas, the total cross-sectional areas increase in proportion to the distances from the source to the respective targets.

4. The semiconductor device of claim 3, further comprising an interlayer dielectric layer which is formed between the global line and the local lines and through which the vias are formed.

5. The semiconductor device of claim 4, wherein a plurality of vias are formed at one or more of the intersections.

6. The semiconductor device of claim 5, wherein the plurality of vias formed at the same intersection are coupled in parallel to each other between the global line and the local line.

7. The semiconductor device of claim 1, wherein the targets are formed at one layer or two or more different layers.

8. A semiconductor device comprising:
a global line coupled to a source;
a plurality of local lines coupled to a plurality of targets, respectively, and arranged at a layer different from a layer where the global line is arranged; and
one or more vias formed at each intersection between the global line and the local lines to couple the global line and the corresponding local line,
wherein the vias formed in the respective intersections are configured to have total cross-sectional areas, and
wherein in the total cross-sectional areas increase in proportion to distances from the source to the respective targets.

9. The semiconductor device of claim 8, further comprising an interlayer dielectric layer which is formed between the global line and the local lines and through which the vias are formed.

10. The semiconductor device of claim 8, wherein a plurality of vias are formed at one or more of the intersections

11. The semiconductor device of claim 10, wherein a plurality of vias formed at the same intersection are coupled in parallel to each other between the global line and the corresponding local line.

12. The semiconductor device of claim 8, wherein the targets are formed at one layer or two or more different layers.

13. The semiconductor device of claim 11, wherein the source includes an output, and the target includes an input.

14. The semiconductor device of claim 13, wherein the output comprises a driver of the semiconductor device, and the input comprises an input gate of a transistor.

15. Routing paths comprising:
a global line; and
a plurality of local lines coupled to the global line,
wherein the length of a routing path includes a section of the global line and a length of a local line, and
wherein loading differences based on length differences between the routing paths are minimized by increasing or decreasing a cross-sectional area of a local line.

16. The routing paths of claim 15, wherein the cross-sectional areas of the local lines increase in proportion with the length of the routing path.

17. The routing paths of claim 15, wherein the global line and the local lines are formed at different layers.

18. The routing paths of claim 17, further comprising:
one or more vias formed at each intersections between the global line and the local lines to couple the global line and the corresponding local line,
wherein the length of a routing path includes a length of the via coupling the global line and the corresponding local line, and
wherein the vias formed at the respective intersections are configured to have total cross-sectional areas, the total cross-sectional areas are increased in proportion with the length of the routing path.

19. The routing paths of claim 18, wherein a plurality of vias are formed at one or more of the intersections.

20. The routing paths of claim 19, wherein the plurality of vias formed at the same intersection are coupled in parallel to each other between the global line and the local line.
